(19) United States
(12) Patent Application Publication
(10) Pub. No.: US 2019/0267171 A1
(43) Pub. Date: Aug. 29, 2019

(54) CABLE DESIGN IN HTS TOKAMAKS

(71) Applicant: Tokamak Energy Ltd., Abingdon, Oxfordshire (GB)

(72) Inventor: Robert Slade, Abingdon, Oxfordshire (GB)

(21) Appl. No.: 16/346,072

(22) PCT Filed: Oct. 10, 2017
(86) PCT No.: PCT/GB2017/053065

§ 371 Date: Apr. 29, 2019

(30) Foreign Application Priority Data
Oct. 31, 2016 (GB) 1618334.5

(51) Int. Cl. H01F 5/04; H01F 6/06; G21B 1/05; G21B 1/21; H01L 39/14; H01L 39/12; H01L 39/24

(52) U.S. Cl. CPC H01F 5/04; H01F 6/06; G21B 1/057; H01L 39/2403; H01L 39/143; H01L 39/125; G21B 1/21

(57) ABSTRACT

There is described a cable for carrying electrical current in a coil of a magnet. The cable comprises a stack of tape assemblies, each tape assembly comprising a high-strength metal substrate layer, and an HTS layer of high temperature superconductor material. The tape assemblies are stacked as a series of type 0 pairs such that the HTS layers of a type 0 pair face each other and the substrate layers of the type 0 pair are separated by the HTS layers.

### FIELD OF THE INVENTION

The present invention relates to the manufacture of superconducting magnets. In particular, the invention relates to the configuration of HTS magnets for use in nuclear fusion reactors, and in particular to HTS magnets for use in tokamak reactors.

### BACKGROUND

The challenge of producing fusion power is hugely complex. Many alternative devices apart from tokamaks have been proposed, though none have yet produced any results comparable with the best tokamaks currently operating such as JET.

World fusion research has entered a new phase after the beginning of the construction of ITER, the largest and most expensive (c15bn Euros) tokamak ever built. The successful route to a commercial fusion reactor demands long pulse, stable operation combined with the high efficiency required to make electricity production economic. These three conditions are especially difficult to achieve simultaneously, and the planned programme will require many years of experimental research on ITER and other fusion facilities, as well as theoretical and technological research. It is widely anticipated that a commercial fusion reactor developed through this route will not be built before 2050.

To obtain the fusion reactions required for economic power generation (i.e. much more power out than power in), the conventional tokamak has to be huge (as exemplified by ITER) so that the energy confinement time (which is roughly proportional to plasma volume) can be large enough so that the plasma can be hot enough for thermal fusion to occur.

WO 2013/030554 describes an alternative approach, involving the use of a compact spherical tokamak for use as a neutron source or energy source. The low aspect ratio plasma shape in a spherical tokamak improves the particle confinement time and allows net power generation in a much smaller machine. However, a small diameter central column is a necessity, which presents challenges for design of the plasma confinement magnet.

An important consideration in the design of spherical tokamaks is the strength of the toroidal magnetic field, B_{T}, which is generated by coils which pass through the central column. The challenge of keeping the central column small enough whilst maximising B_{T} is addressed in this document by the use of high temperature superconductor material (HTS) in the toroidal field coils.

The configuration of the conductors used to make such HTS coils has a significant bearing on the field obtainable and thus the efficiency of the reactor.

### SUMMARY

In accordance with one aspect of the present invention there is provided a cable for carrying electrical current in a coil of a magnet. The cable comprises a stack of tape assemblies, each tape assembly comprising a high-strength metal substrate layer, and an HTS layer of high temperature superconductor material. The tape assemblies are stacked as a series of type 0 pairs such that the HTS layers of a type 0 pair face each other and the substrate layers of the type 0 pair are separated by the HTS layers.

Each type 0 HTS layer may include an internal layer of copper, of thickness between about 40 μm and about 800 μm, placed between the tape assemblies of the type 0 pair. Each tape assembly may include a silver layer adjacent the HTS layer (on the opposite side of the layer to the substrate). The internal layer of copper will then contact the silver layer of each tape of the type 0 pair. The internal layer of copper of each type 0 pair may overhang the edges of the tape for electrical connection to an adjacent type 0 pair in the stack. This thick layer of copper should not significantly inhibit current sharing between the HTS layers of the type 0 layer, but may assist with current sharing between HTS layers in different type 0 pairs. The electrical connections may be at both edges of the HTS tape or optionally only at one edge or alternating edges. The connection of the overhanging copper layers between type 0 pairs may be a pressed, crimped or soldered connection.

The stacks of type 0 tape pairs may be arranged side-by-side with thermally and electrically conductive segments between the stacks. Some or all of the thermally conductive segments may contain channels for the flow of cryogenic coolant.

The tape assemblies may be incorporated in a copper matrix and/or in a high strength structural jacket formed from material such as stainless steel or inconel.

Optionally there is at most 50 μm of copper between adjacent type 0 pairs of tape assemblies in the stack. In other words, most of the copper in the stack may be internal to the type 0 pairs. It may even be that there is no more than a few microns of copper between adjacent type 0 pairs, or even no copper at all between adjacent type 0 pairs.

In accordance with another aspect of the present invention there is provided a cable for carrying electrical current in a coil of a magnet. The cable comprises a stack of tape assemblies and copper layers, each tape assembly comprising a substrate layer and an HTS layer of HTS material. The tape assemblies are stacked such that there is a layer of copper of thickness at least 100 μm, preferably at least 200 μm, more preferably at least 400 μm facing the HTS layer of each tape assembly. This copper assists in getting the current out of the HTS layer and distributing it to other HTS layers in the stack.

The tape assemblies may be stacked in alternating type 0 and type 2 pairs, such that there is a layer of copper of thickness at least 40 μm, preferably at least 200 μm, more preferably at least 400 μm within each type 0 pair.

In accordance with another aspect of the present invention there is provided a cable for carrying electrical current in a coil of a magnet. The cable comprises a stack of tape assemblies, each tape assembly comprising a high-strength metal substrate layer, and an HTS layer of high temperature superconductor material. The tape assemblies are stacked as a series of type 2 pairs such that the substrate layers of a type 2 pair face each other and the HTS layers of the type 2 pair are separated by the substrate layers. A layer of copper of thickness at least 100 μm, preferably at least 200 μm, more preferably at least 400 μm may be located between each type 2 pair.

The HTS layer in any of the cables described above may include ReBCO material.

Any of the cables described above may be configured to carry electrical current between joints with further cables.

The number of tape assemblies in the stack may vary along the length of the cable. The width of the tape assemblies may vary along the length of the cable.

Optionally the substrate does not contain nickel.

The invention also provides a field coil comprising two or more cables as described above electrically connected at respective ends by a joint, optionally a praying hands joint or a scarfed joint.

A copper lamination between tape assemblies in a pair of tape assemblies may be replaced in the joint by a pair of HTS tape assemblies. Alternatively, a copper lamination between tape assemblies in a pair of tape assemblies may extend continuously into the joint. In another embodiment, each pair of tape assemblies may be terminated with a copper jointing piece for pressing together.

The invention also provides a nuclear fusion reactor comprising a plasma vessel and a set of field coils for generating magnetic field where the field coils are as described above.

### BRIEF DESCRIPTION OF THE DRAWINGS

Some preferred embodiments of the invention will now be described by way of example only and with reference to the accompanying drawings, in which:

FIG. 1 is a schematic elevation view, half section, of a compact spherical tokamak;

FIG. 2 is a graph showing typical critical current performance for several Zr-doped ReBCO tapes vs applied magnetic flux density, where the field is parallel to the crystalline c-axis;

FIG. 2B is a graph showing enhancement of critical current relative to the values shown in FIG. 2A as a function of angle of the applied magnetic field relative to a normal to the plane of the tape;

FIG. 3 is a schematic representation of a high temperature superconductor tape assembly;

FIG. 4A is a graph illustrating variation in magnetic field intensity with radius in a toroidal field coil for a tokamak;

FIG. 4B is a schematic illustration of graded numbers of tapes in a field coil of a tokamak;

FIGS. 5A and 5B are schematic illustrations of a jointed magnet;

FIG. 6 is a schematic illustration of a two HTS tape assemblies modelled as a resistor network;

FIG. 7 is a schematic illustration of tapes stacked in type 0, type 1 and type 2 pairs;

FIGS. 8A and 8B are graphs showing the result of modelling of different widths of tape assemblies configured in different types of stacking pairs;

FIG. 9 is a graph illustrating how critical current fluctuates along a tape associated with fluctuations in the ReBCO deposition process;

FIG. 10 shows current sharing between tapes arranged in type 0, type 1 and type 2 pairs around a dropout in critical current in one tape of the pair;

FIG. 11 is a cross section through a type 0 pair building block for a cable;

FIG. 12 is a schematic illustration of current sharing in a cable including eight type 0 pairs;

FIG. 13 is a schematic cross section through a cable arrangement with three stacks of four type 0 pairs of tape assemblies; and

FIGS. 14, 15 and 16 are schematic illustrations of three forms of scarfed shaking hands joints.

### DETAILED DESCRIPTION

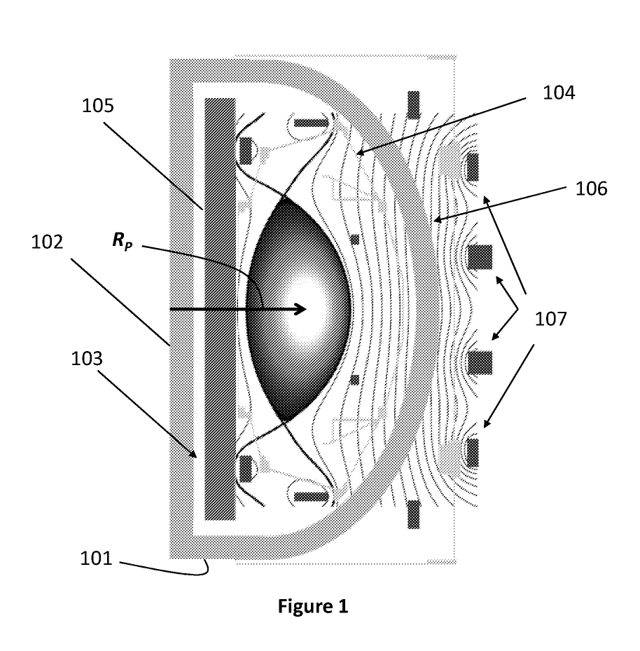

A compact spherical tokamak (ST) with a low aspect ratio (eg: 1.7-1.8), suitable for a D-T nuclear fusion power plant, such as that described in WO 2013/030554, requires a toroidal plasma confinement magnet with a very slim central column. Subsequent analysis indicates that a device with a major plasma radius R_{P} between 1-2 m is suitable as a pilot plant to achieve or exceed break-even fusion power generation. FIG. 1 is a schematic illustration of a cross section (elevation view, half section) through a compact ST of the type described. The tokamak includes a plasma confinement magnet 101 capable of generating a static toroidal magnetic flux density B_{T} of a few Tesla at R_{P}. To generate this field, a current of approximately 20-30 MA must flow axially in a central column 102 of a toroidal field (TF) magnet 101. FIG. 1 shows one coil of the TF magnet 101: it will be appreciated that there are many such coils arranged azimuthally around the tokamak. FIG. 1 also shows a return limb 106 of the TF coil and poloidal field coils 107, which generate an axial magnetic field used to control the position and stability of the plasma current. The discussion within this application focuses on the TF coils, but is equally applicable to PF coils.

The minimum radius for the superconducting core 102 for the pilot magnet is limited by peak magnetic stress and quench protection considerations to approximately 20-25 cm, which leaves ˜40 cm radial space for thermal insulation 103 of the plasma chamber 104 and magnet cryostat plus a neutron shield 105. At this radius, the required engineering current density Jₑ in the core is ˜150-200 A/mm² and the peak magnetic flux density at the surface of the core is 20-25 T.

Traditional low temperature superconductors (LTS) such as Nb₃Sn, have superconducting transition temperature of ˜19 K but would need cooling below 2 K to provide the required engineering current density in these magnetic fields, which would result in a bulky and extremely expensive cryogenic system. However, the second generation of high temperature superconductor (HTS) wires, which have transition temperature ˜90 K, can readily achieve the required current density in magnetic fields up to ˜25 T even when operated at temperatures in the range 20-40 K. This temperature range is chosen in preference to a lower temperature (which would reduce the quantity of HTS required) because it minimises the overall system cost by trading off the cost of extra HTS against the lower cryogenic cooling costs resulting from the greater Carnot efficiency available at higher temperature.

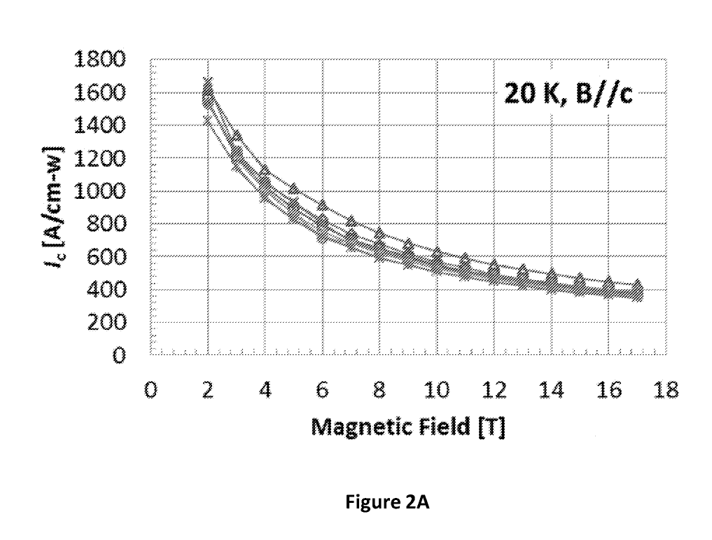

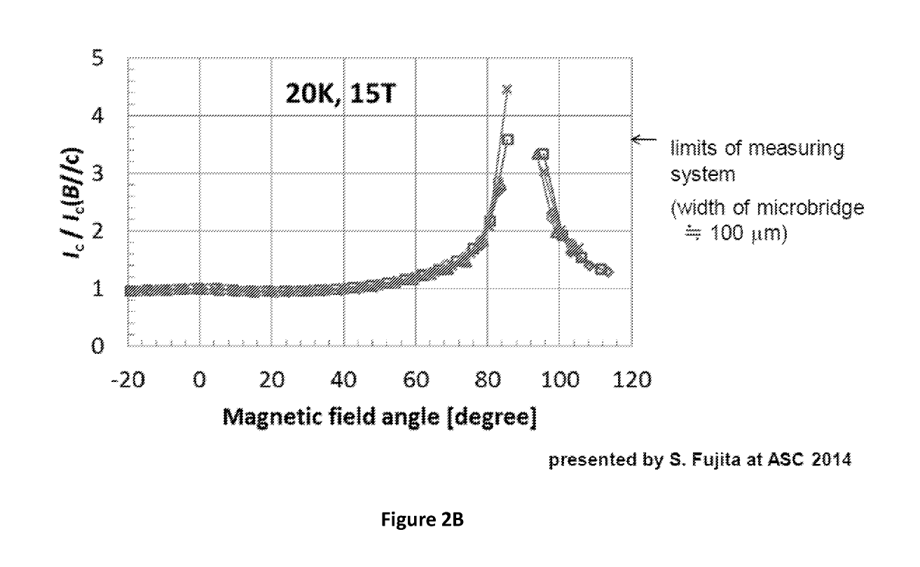

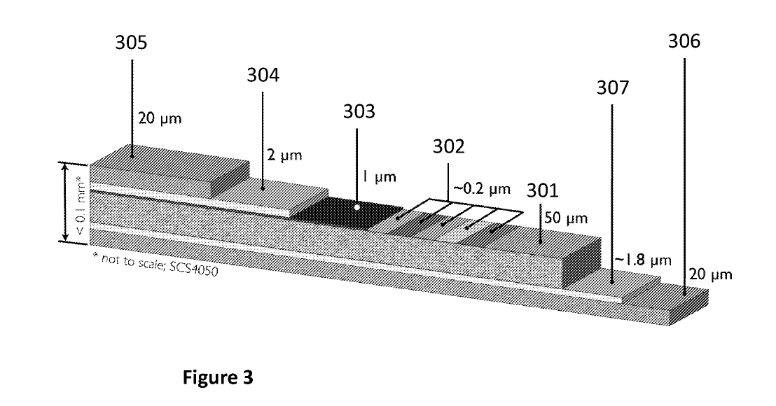

Second generation HTS materials are generally referred to as ReBCO (≡(Re)Ba₂Cu₃O₇₋ₓ where Re represents a rare-earth element such as Y or Gd). ReBCO wires are available in the form of coated tapes (an example is shown in FIG. 3 and discussed in more detail below). FIG. 2A shows the typical critical current (I_{C}) performance at 20 K (in amps per cm width of tape) for several Zr-doped ReBCO tapes vs applied magnetic flux density up to 17 T, where the field is parallel to the crystalline c-axis (ie: normal to the plane of the tape). Doping with Zr is a method used to add flux pinning centres which enhance the critical current. FIG. 2B shows enhancement of I_{C} relative to the values shown in FIG. 2A as a function of angle θ of the applied magnetic field relative to a normal to the plane of the tape. The performance at θ˜90° (i.e. magnetic field parallel to the crystalline ab axis) is significantly enhanced, and indeed beyond the current capability of the test rig used to acquire the data in FIG. 2B. An enhancement in I_{C} of 5 or more is feasible when the field is parallel or close to parallel to the tape plane.

ReBCO wire technology is still evolving but commercial coated conductor tapes are already available from several manufacturers with engineering performance suitable for a fusion power plant. They are manufactured by deposition of typically 1-2 μm layer of ReBCO ceramic superconductor 303 on a suitably prepared high strength substrate 301 (typically stainless steel or Hastelloy) as shown in FIG. 3. The crystalline ReBCO layer is usually deposited by IBAD or magnetron sputtering on top of a series of buffer stack layers 302, each approximately 0.2 microns thick. A 1-2 μm layer of silver 304 is deposited on the ReBCO layer to make electrical contact and isolate it from an upper copper layer 305, which would deplete oxygen from the ReBCO if it were in direct contact. Manufacturers offer the option to either electroplate the silver plated tape with thin layers (typically ˜20 μm) of copper “stabilizer” 305, 306, or laminate the tape with thicker copper layers. The primary function of the Cu stabilizer 305, 306 is to provide an alternative path for current should the tape locally quench (ie: revert to a resistive or “normal”, non-superconducting, state). The consequences of a quench will be discussed in more detail later.

Typically, the thickness of a tape, including substrate and 20 μm Cu stabilizer plating, is 100-150 μm, hence the engineering current density of a single tape with performance as shown in FIGS. 2A & 2B is ˜350 A/mm² at 20 K and 17 T for field perpendicular to tape and >1700 A/mm² for field parallel to the tape. Since this is higher than the average Jₑ required over the whole central column area, there is space for cryogen channels, structural material and, most importantly, additional copper for quench protection.

The voltage across a length of HTS tape depends on transport current I in a highly nonlinear way:

$${V}_{HTS} = {{E}_{0} ( \frac{I}{{I}_{C}} )}^{n}$$

where E₀=100 nV/m is the defined critical current criterion and n is an experimental parameter that models the sharpness of the superconducting to normal transition; n is typically in the range 20-50 for ReBCO. Depending on the value of n, the voltage is negligible for values of α=I/I_{C}<˜0.8.

In a practical TF magnet the ˜25 MA current that must flow in the centre column will be partitioned across a number of turns, which in turn are split into a number of TF coils (typically 8-16, depending on field quality considerations). A number of factors must be considered when choosing the exact number of turns, but generally a high transport current is preferred to minimise the magnet's inductance. This in turn minimises the voltage developed when the magnet is shut down, as in the event of a quench (discussed below). A typical number of turns within the central column would be 256 (eg: 16 turns in each of 16 TF coils) resulting in a transport current of approximately 100 kA per turn.

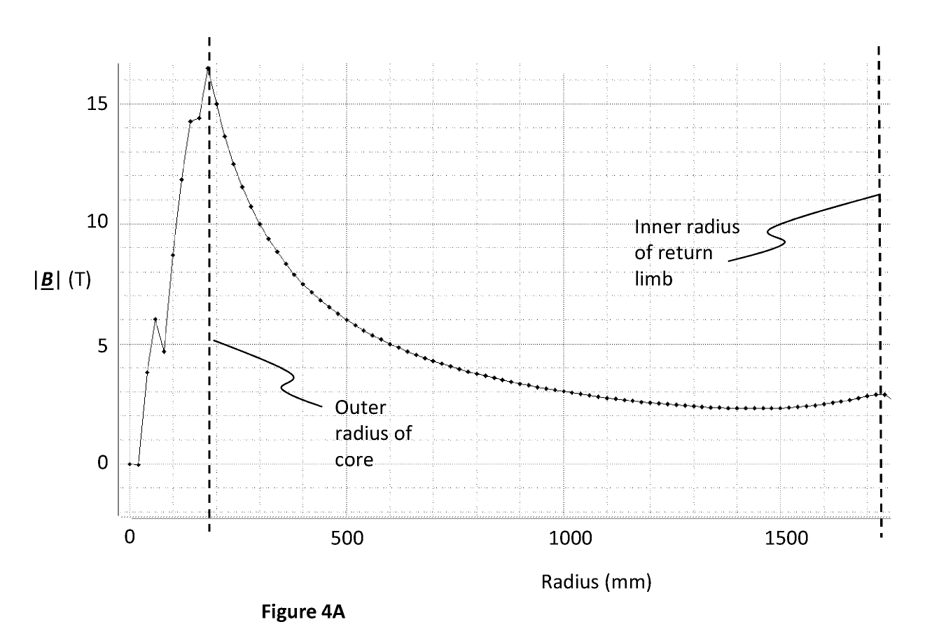

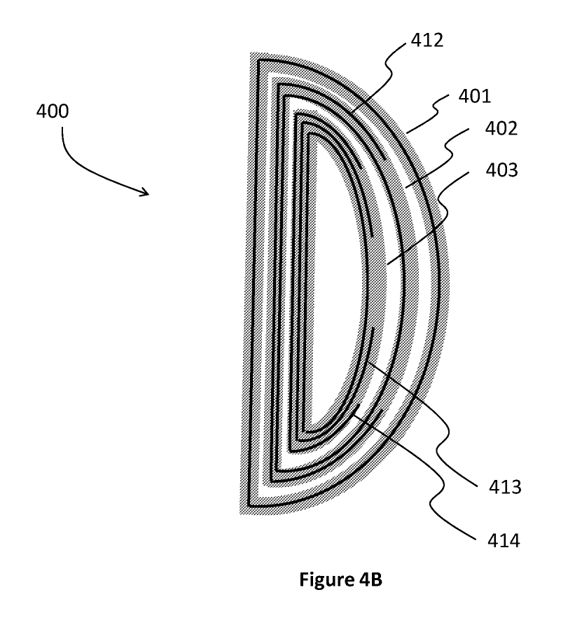

The critical current of a single ReBCO tape at 20 K operating in a field of 20 T parallel to the plane of the tape is ˜1800 A/cm-width. So assuming operation at 70% of I_{C}, each turn in the outermost layer of the central column would require seventy 12 mm wide tapes connected in parallel to carry the necessary transport current (I). A portion of turn comprising multiple tapes is referred to as a cable section. The actual number of tapes needed in any cable section will depend on the local I_{C} (B, T, θ) at the position of the turn within the magnet. The highly enhanced I_{C} around 0=90° allows fewer tapes to be used to carry the same total current in situations where the tapes can be aligned parallel to the prevailing magnetic field direction; this is the case in the TF magnet's central column. The magnetic field within the core is proportional to radius, so cable sections at smaller radii need fewer tapes to carry the same transport current. The magnetic field also decreases in the return limbs with radius, so the number of tapes within a cable section could be graded along its length. The variation in magnetic field intensity |B| with radius in a TF coil for a tokamak is shown in FIG. 4A. This plot is for a tokamak with major radius 0.6 m, but the field profile will be similar for a larger tokamaks: a magnet for a tokamak with major radius 1.4 m will be similar, with magnetic field scaled to ˜22 T at the core radius of ˜22 cm.

It is therefore desirable to change the number of tapes between turns and within each turn, to minimise the total amount of HTS conductor used in the magnet. This implies the need for easy commutation of current between tapes in a cable section and for joints between cable sections. This is illustrated schematically in FIG. 4B, which shows a schematic TF coil 400 with three radial layers, one turn per layer, 401, 402, 403. The turns have radially graded numbers of tapes: one tape in the outer turn 401, which passes through the smallest radius in the core, two tapes in the middle turn 402 and three tapes in the inner turn 403, which is at the surface of the core where the magnetic field is most intense. This illustrates radial grading of tapes between turn layers. In the return limbs, one 412 of the two tapes in the middle turn 402 is removed over the portion of the turn where the magnetic field is least intense, and two 413, 414 of the three tapes in the inner turn 403 are removed over the portion of the turn where the magnetic field is least intense. This illustrates longitudinal grading of tapes within a single turn. Both types of grading require low resistance joints between tapes in a cable section and between cable sections.

It is not yet possible to join HTS tapes without introducing a small resistance. However, operation at 20-40 K makes a magnet with multiple slightly resistive joints feasible, because the additional ohmic heating can be balanced using a lower power refrigerator than would be needed in a jointed LTS magnet, thanks to the higher Carnot efficiency available at higher temperatures. Several researchers have demonstrated that nano-ohm joints between 100 kA ReBCO cable sections are possible (Yanagi, Nagato, et al, “Feasibility of HTS magnet option for fusion reactors.” Plasma and Fusion Research 9.0 (2014): 1405013-1405013). Having at least two joints in each turn also enables the magnet to be potentially demountable, for ease of manufacture and maintenance (Sorbom, B. N., et al. “ARC: A compact, high-field, fusion nuclear science facility and demonstration power plant with demountable magnets.” Fusion Engineering and Design 100 (2015): 378-405.).

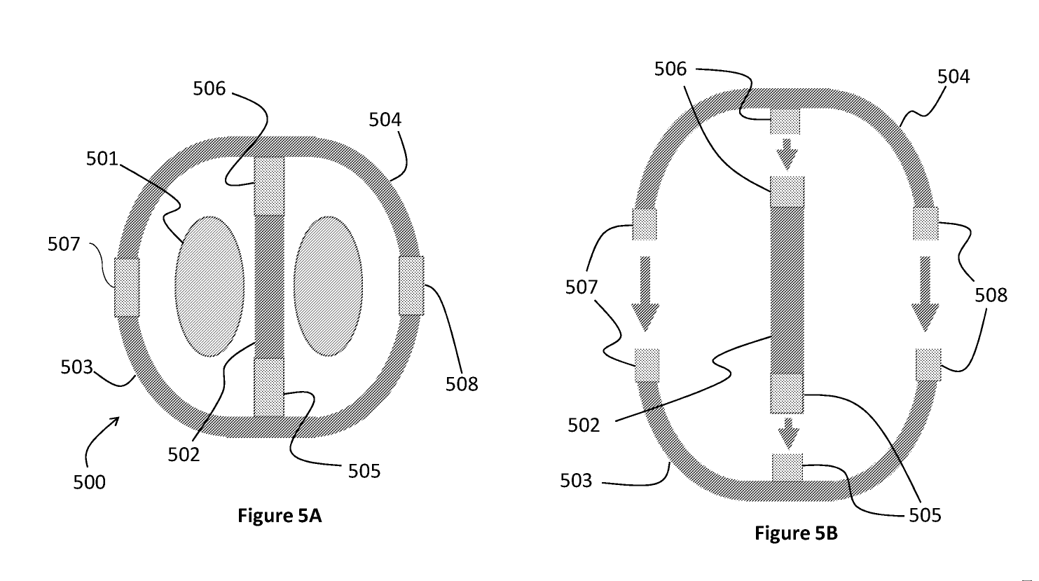

An example of a jointed magnet is shown schematically in FIG. 5, where FIG. 5A illustrates a section through the TF magnet 500 of a ST in which plasma 501 is confined. The magnet includes a central column 502 which includes HTS tape, and return limbs 503, 504, also including HTS tape. The return limbs 503, 504 are connected to the central column 502 by joint stacks 505, 506, and also include joint stacks 507, 508 half way around the return path. This enables the return limbs 503, 504 to be manufactured as separate entities to the central column 502. The magnet can then be assembled from a series of modules, as shown in FIG. 5B. Other joint configurations are clearly possible. This has the significant advantage that the plasma vessel, and other requirements such as any PF coils which ultimately need to be located inside the TF coils, need not be manufactured in situ within the TF coils. It also makes it possible to disassemble the TF coils for maintenance, and even allows for the possibility of a replaceable central column, a desirable feature of a power reactor, since the current carrying performance of HTS is anticipated to degrade in the neutron flux and the central column will receive the highest dose.

As mentioned, a magnet with a large number of joints is viable if the ohmic heat load added to the magnet's cold mass is less than, or similar to, the heating due to 14 MeV neutron flux. For the compact ST pilot described above, the neutron heat load has been calculated to be roughly 30 kW (Windsor, C. G., J. G. Morgan, and P. F. Buxton. “Heat deposition into the superconducting central column of a spherical tokamak fusion plant.” Nuclear Fusion 55.2 (2015): 023014.), so an additional 10-30 kW of joint heating would be acceptable for a commensurate increase in cryoplant cooling capacity. Assuming three joints per turn and a limit of 15 kW of extra heat load, the acceptable resistance for each joint is 1 e4/(1 e5²*3*260)=2 nΩ, which has been demonstrated in a 100 kA cable section (Ito, Satoshi, et al, “Bridge-type mechanical lap joint of a 100 kA-class HTS conductor having stacks of GdBCO tapes,” Plasma Fusion Res 9.2 (2014).).

A jointed magnet also allows more efficient use of HTS tapes because much shorter individual lengths of HTS tape are needed than would be the case in a magnet with coils wound from continuous cable. HTS tape is generally very much cheaper when purchased in short lengths because the manufacturing process is prone to fluctuation in I_{C} along the length of the tape, with occasional dropouts (regions of tape with substantially lower I_{C}). These flaws normally have to be cut out by the manufacturer as part of the quality control process, reducing the yield of long tape lengths. A compact TF magnet made from pre-formed cable sections joined at the top, and optionally at the bottom, of the core, and also in the middle of the return limbs, as shown in FIG. 5, would only require maximum piece-lengths of roughly 6-8 m in the core and 12-20 m in the return limbs, depending on the exact configuration and magnet size. A jointed magnet thus allows use of much shorter individual lengths of HTS tape than would be needed for more conventional magnets made from layer wound pancake coils, for example. As previously mentioned, grading of the number and lengths of tapes used within each cable section will also significantly reduce the total amount of tape needed.

A consequence of the use of cable section joints and tape grading is the necessity for good current sharing between tapes within a single cable segment. It is therefore desirable to provide a practical method of ensuring high conductivity between all tapes in a stacked-tape cable to promote easy current sharing, as will be described.

In most prior art, cables for fusion magnets (both LTS and HTS concepts) are normally designed with transposition and/or twisting of the strands (or tapes in the case of HTS), using Rutherford or Roebel cable layouts. This is done to reduce coupling losses which is important in AC or fast ramped magnets, such as accelerator magnets. However, transposition and twisting may not be essential for the TF coils of a superconducting fusion magnet, since it will be operated in quasi-static mode and energized slowly. Twisting of the cables has the significant disadvantage that it removes the option to utilise the higher I_{C} available when the tapes are aligned with the local magnetic field vector. In the present disclosure the cables are described without the complication of transposition or twisting, but it will be apparent that the techniques described are also applicable to twisted and/or transposed cable construction.

A critical consideration for a reliable large scale superconducting magnet, and in particular an HTS magnet, is quench protection. If the transport current exceeds the local critical current I_{C} in any length of a single HTS tape, a voltage is developed across the length according to the V-I relation above. The excess current above I_{C} is carried by the copper stabilizer layer. This condition is often referred to as a “quench”, but it is better referred to as a “pre-quench” if we reserve the term quench to refer to a thermal runaway condition, leading to magnet shutdown. A pre-quench can occur if there is a reduction in local I_{C} in one or more tapes caused by (i) a rise in temperature, (ii) an increase, or change in angle, of the magnetic field, or (iii) physical damage to the ReBCO layer (eg: cracking caused by excessive strain or fatigue). It can also occur during redistribution of current between tapes in the cable as a consequence of a local I_{C} degradation in another tape.

If the change that caused the localized pre-quench is transient, and the associated injected energy less than the minimum quench energy (MQE), it is possible for the cable to recover. If, however, the change in I_{C} is permanent, or the injected energy pulse is above MQE, a thermal runaway will occur (a true “quench”). If palliative action is not taken quickly the hot spot temperature will increase rapidly, quickly resulting in melting of the conductor materials, voltage breakdown, and ultimately to damage to the local turn or coil, or even destruction of the magnet due to an imbalance of electromagnetic forces.

It is therefore imperative to detect a hot spot quickly and execute a controlled magnet shut-down before damage occurs. This is normally done by opening a circuit breaker to divert the magnet's transport current through a dump resistor, (hence this method is called “detect and dump” quench protection). This is the standard active protection method for any large superconducting magnet with high stored energy, and there are a number of variations on the theme (eg: use of heaters, eddy currents of AC losses to force faster propagation of the quench region, driven either by an external power supply or utilizing the magnet's own stored energy). Active protection is essential for large HTS magnets because the higher heat capacities of materials at temperatures of 20 K and above results in much slower propagation of the quenched (ie: normal) zone compared to LTS. The normal zone propagation velocity (NZVP) is only mm/s in ReBCO compared to m/s in Nb₃Sn. During an unprotected quench a HTS magnet's stored energy would therefore be dissipated over a much smaller volume than would be the case for an LTS magnet of equivalent stored energy, resulting in a more rapid local rise in temperature. This calls for faster quench detection in the order of tens of milliseconds for HTS compared to seconds for LTS.

It is therefore desirable to minimize the likelihood that a localized reduction in I_{C} in a single tape will result in a hot spot forming and leading to thermal runaway.

An HTS cable comprising several individual tapes capable of carrying 100 kA for a compact high field spherical tokamak therefore has the following desirable characteristics:
1. A sufficient number of HTS tapes in parallel, sharing the transport current.
2. Sufficient copper stabilizer connected to the HTS with low resistance to carry the transport current in the event of a quench for the time required for detection of the quench and de-energization of the magnet, such that the temperature of the hot-spot does not exceed a safe temperature (e.g. 300 K).
3. Adequate cooling to remove heat from (i) neutron interactions, (ii) joint heating, (iii) local heat generated in small sections of tape where local I_{C} dropouts cause a fraction of the transport current to flow in the copper stabilizer, and (iv) radiation and conduction heat load from the environment.
4. Structural support to withstand the electromagnetic forces acting on the cable without exceeding the strain limits of the HTS or other materials, or causing local stress concentrations.
5. Material properties chosen to avoid stress and fatigue problems during thermal cycling of the magnet between room temperature and operational temperature, and during energization and de-energization.
6. Adequate insulation between turns to avoid voltage breakdown in the event of a rapid shut-down of the magnet.
7. Where possible, such as in the central core, arranging the a-b axis of the ReBCO layer (in the plane of the layer) to be oriented parallel to the magnetic field to maximise the I_{C} of the tape.
8. Varying the number of tapes between turns radially within the magnet central column to keep α=I/I_{C} (B, T, θ) approximately constant.
9. Varying the number of tapes along any single turn to keep α approximately constant along the turn. In practice, this applies mostly in the return limbs, because the field and temperature do not vary significantly along the axis of the central column.
10. The cable design being compatible with low-resistance, compact and demountable joints between cable sections.
11. Being constructed from HTS tapes with optimized design (e.g. thin substrate layer, low interfacial resistivity from HTS-Ag layer, thick ReBCO layer to carry maximum current, I_{C} optimized to suit the prevailing (B, T, θ) at that position within the magnet.

Before considering changes in current distribution between tapes it is first necessary to determine what factors control the initial apportionment of current between tapes in a stack. It has previously been identified (Zermeno, Victor, et al. “Modeling and simulation of termination resistances in superconducting cables.” Superconductor Science and Technology 27.12 (2014): 124013., and Bromberg, L., et al. “Current distribution and re-distribution in HTS cables made from 2nd generation tapes.” ADVANCES IN CRYOGENIC ENGINEERING: Transactions of the Cryogenic Engineering Conference-CEC, Volume 57. Vol. 1434. No. 1. AIP Publishing, 2012.) that, if the superconducting properties of all the tapes are similar, then the termination resistances of each individual tape, at the joints at either end of the cable, play the primary role in determining how transport current is shared between the tapes. Conversely, if the termination resistances of all tapes are equal, then current will share according to the variation in superconducting properties between tapes, with the tapes having the highest I_{C} and lowest n value “filling up” first because they have the most negligible resistance. Furthermore, the self and mutual inductances of the tapes will vary according to their topology and relative positions within the cable and magnet, and hence they will present different impedances during ramping up the transport current. After ramping up, currents will redistribute between tapes with characteristic time constants proportional to the ratio of reactive and resistance impedances between the tapes (L/R). It is desirable to minimise R to encourage rapid settling of currents. All these effects influence the initial distribution of current between tapes in any cable segment in a complex way and the final stable current distribution can be expected to be grossly uneven.

In Zermano's analysis the transverse conductivity between tapes was neglected. This is also the case in cables designed for power transmission (e.g. Amemiya, N. et al. “Current redistribution and stability of superconducting triplex cable without electrical insulation carrying non-uniform current.” Cryogenics 43.3 (2003): 249-254.), where generally little attempt is made to reduce resistivity between tapes within the cable since the risk of quench is low due to the low stored energy in these applications. However, a large high field magnet will benefit from high conductivity between tapes, allowing current to share easily between tapes and copper stabilizer, increasing the time that a pre-quench takes to develop into an irrecoverable thermal runaway. Bromberg recognises the importance of current transfer between tapes in a stack and proposes soldering pieces of HTS tape to the sides of the stack to act as periodic shunts along the cable. The shunts locally reduce the transverse resistance between tapes and encourage current sharing. This approach has several disadvantages: (i) it is not possible to apply the side tape continuously because it would make the cable inflexible, so current sharing only occurs periodically where there are shunts, (ii) the side tape is orthogonal to the main stack so will have significantly reduced critical current if the tapes in the stack are oriented parallel to local magnetic field, and (iii) the side tape could quench if more than one tape in the stack failed between adjacent shunts and their combined current had to pass through a single shunt.

A more practical method of ensuring isotropic high conductivity between tapes in a stacked tape cable is required. To address this need a simple model of a pair of tapes has been developed which allows investigation of the effect of cable construction on current sharing between tapes.

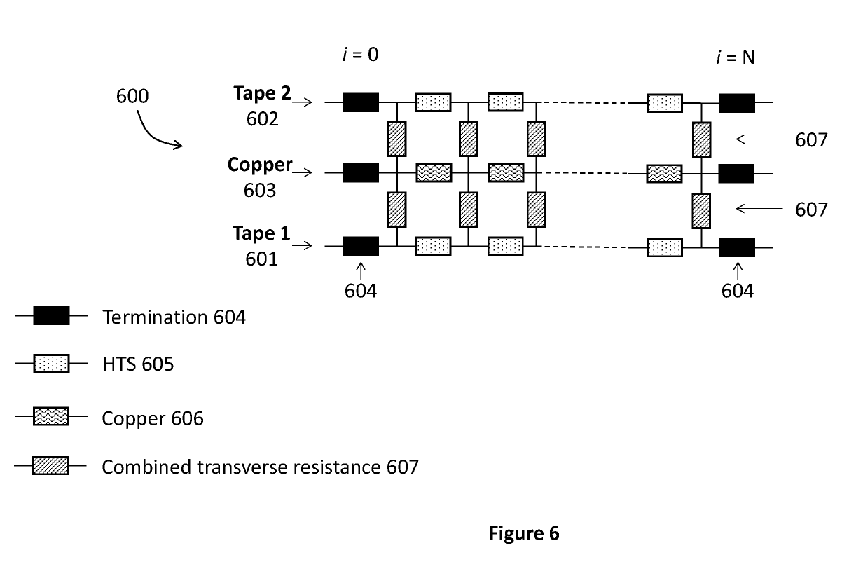

A simplified cable consisting of two tapes can be modelled as a resistor network 600, as shown in FIG. 6, which shows the equivalent circuit. There are three longitudinal (ie: along the length of the cable) conduction paths 601, 602, 603. Two of the paths 601, 602 are HTS paths and one 603 is through the copper “filling” between the HTS layers in a sandwich. The cable is discretized into short lengths dx and each longitudinal conduction path is modelled as a number of series connected resistive elements, with termination resistances 604 representing the resistive joints at each end. The resistance of the HTS elements depends on transport current I according to the V-I relationship:

$${R}_{HTS} = \frac{{E}_{0}}{I} {( \frac{I}{{I}_{C}} )}^{n}$$

The HTS sections 605 can thus be modelled using a network of current dependent resistances R_{HTS_j,i}=E0*dX*I(j,i)^{(n(j,i)-1)}*I_{C}(j,i)^{-n(j,i)}, where j represents the tape number (1 or 2 for a two tape model) and i the axial position of the element. I_{C}(j,i) and n(j,i) can be pre-calculated. The longitudinal resistance to current passing along the copper layer is shown as a string of identical series connected resistors 606. The longitudinal elements are connected by transverse resistors 607 which model the HTS-Ag—Cu interface layer resistances plus the transverse resistance of the copper paths between conduction paths—i.e. the resistance seen by current transferring from the HTS elements 605 to the copper elements 606. The transverse resistances can be pre-calculated from knowledge of materials, geometry and prevailing temperature and magnetic field (incorporating magnetoresistance effects). The resistance of the substrate and buffer layers are very large compared to other materials, and these layers can be considered as insulators.

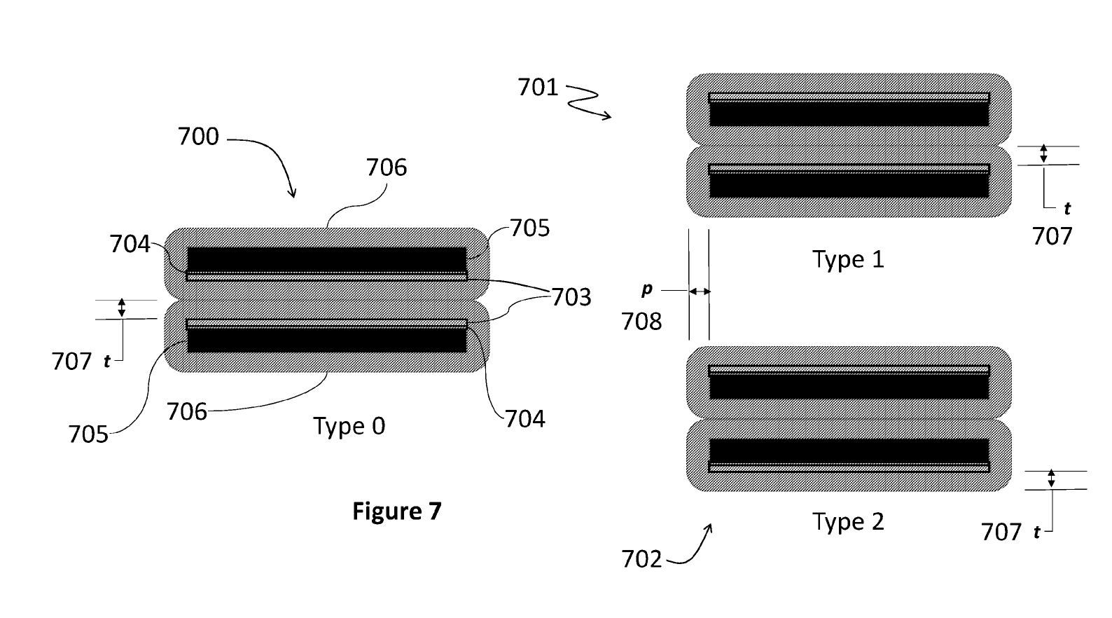

Before we can use this model we must calculate the transverse resistances. These depend strongly on the geometry of the paths connecting the ReBCO layers of each tape. The topology of the tape layup and the thickness of the copper layers between the tapes, and at the edges of the tapes, both influence resistivity. These effects can conveniently be calculated using 2D finite element analysis (FEA). The possible ways for tapes to be stacked are illustrated in FIG. 7, which shows three arrangements 700, 701, 702, wherein each tape has a silver layer 703, a ReBCO layer 704, a substrate layer 705, and a copper stabilizer layer 706:
Type 0 (700): ReBCO face 704 to ReBCO face 704
Type 1 (701): ReBCO face 704 to substrate 705, with ReBCO layers 704 connected via the edge copper only (considering the substrate to be an insulator).
Type 2 (702): substrate 705 to substrate 705, with ReBCO layers 704 connected via the edge copper only, a longer path than Type 1.
   The key geometry parameters are the thickness t of the copper lamination or electroplating on the ReBCO side of the tape, and the width p of the copper at the edges of the tape. The tapes' copper surfaces were modelled as being joined using a 10 μm thick layer of solder.

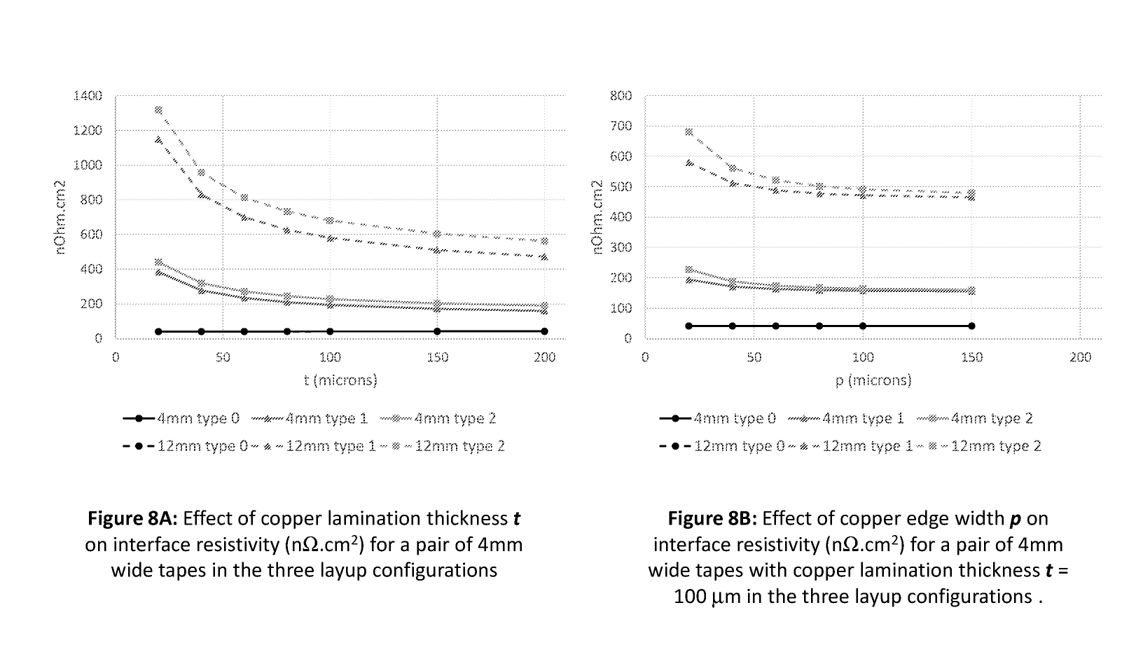

The three layup types were modelled using FEA and the interface resistivity between the ReBCO layers determined as a function of t and p. The results are shown in FIGS. 8A and 8B, for type 0 joints, type 1 joints and type 2 joints and tape widths of 4 mm and 12 mm. It is clear from the FEA results that thicker copper t between tapes in a pair has negligible impact on the interface resistivity for type 0 joints—this is dominated by the ReBCO—Ag—Cu interface resistivity. Similarly, wider edge copper p has no effect on type 0 layup resistivity because current does not flow in the edge region. However, FIG. 8A demonstrates that thicker copper stabilizer layers laid up against the ReBCO side of tapes in both type 1 and type 2 layups markedly reduced the interface resistivity; this is because it allows current to flow out of the ReBCO layer over a larger proportion of the tape width. Increasing the copper stabilizer thickness per tape t on the ReBCO side of the tape from the standard 20 μm to 100 μm nearly halves the resistivity, further increases have a small but beneficial effect. Similarly, it is clear from FIG. 8B that increasing the width of the copper p joining the tapes at the edges is also beneficial in type 1 and 2 layups because the edge region is a bottleneck for current transfer if it is too narrow. There is little advantage in increasing p>t. However, it should be noted that the FEA models give ideal results and neglect the vagaries of “real world” solder connections. It is likely that wider edge connections would benefit real joints.

Another conclusion that can be drawn from FIG. 8A is that, for minimum inter-tape resistance, it is better to use three stacks of 4 mm wide tapes than a single stack of 12 mm wide HTS tapes, since the interface resistivity for a 4 mm tape is significantly lower than for a 12 mm tape.

Assuming that 50% of the area of the central column is occupied by cooling channels and structural material (e.g. stainless steel) the required Jₑ per tape in the core of a tokamak with major radius 1.4 m is ˜330 A/mm². This allows space for up to 400 μm thickness of Cu stabilizer on the ReBCO face of each tape, so increasing the tape copper lamination thickness to 100 or 200 μm is perfectly feasible, and leaves space for substantial and practical edge connections.

If the thickness of the copper stabilizer is increased without regard to the space available it leads to marginal further reduction in resistance for type 1 and 2 joints, but only up to the point at which current is leaving and entering each tape uniformly over its whole width. Beyond this thickness it becomes slightly detrimental because the resistive path between tapes becomes longer.

Having determined the transverse resistivities the numerical model described above can now be used to calculate how current transfers from one tape of a pair to the other tape. Particular thought has been given to the situation where there is a sharp I_{C} dropout in a single tape, causing current to divert into the copper and the second tape.

Starting from a guessed solution of all current flowing in one tape only, or equal currents in each tape, the actual current distribution I_{i,j} can be found by minimizing the total power dissipation in the resistor network 600, with a constraint that the longitudinal currents at each step sum to the stipulated transport current I (hence obeying Kirchov's current law). The model can be run for various transport currents, and a V-I characteristic for the stacked-tape cable may be plotted.

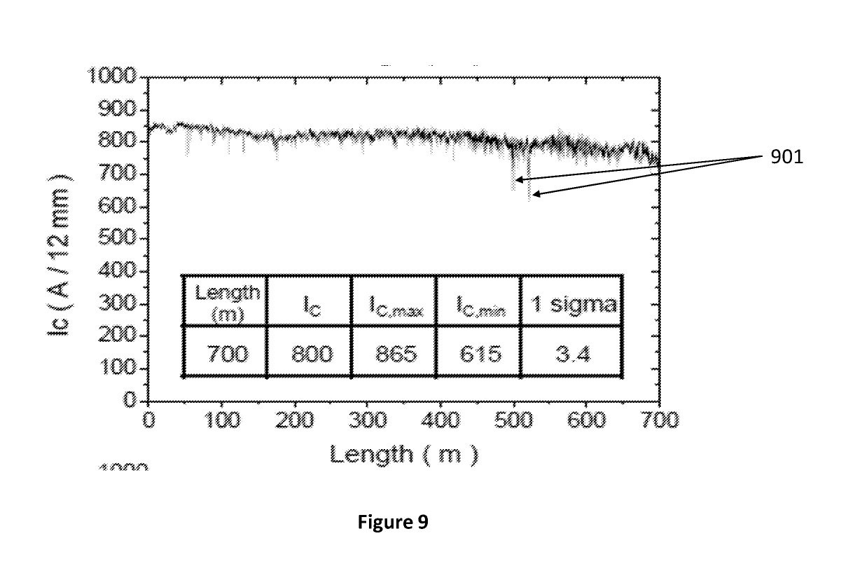

This is particularly importance when considering the fluctuation in I_{C} along each tape, caused by manufacturing variations. A number of manufacturing processes (eg: MOD, PLD, MOCVD, RCE) are used to deposit the ceramic ReBCO layer, but real tapes all display a variation in critical current along the length of the tape. There are occasional sharp dropouts in I_{C} 901 associated with fluctuations in the ReBCO deposition process, as shown in FIG. 9

The most severe dropouts are typically cut out as part of the quality control process, reducing the manufacturing yield of long lengths of HTS and increasing the cost. However, some may be missed, particularly if they are very short in length (a mm or less), and these could form dangerous hot spots if undetected. Therefore, it is highly desirable to develop a cable that can tolerate the impact of occasional short but deep drop in I_{C}.

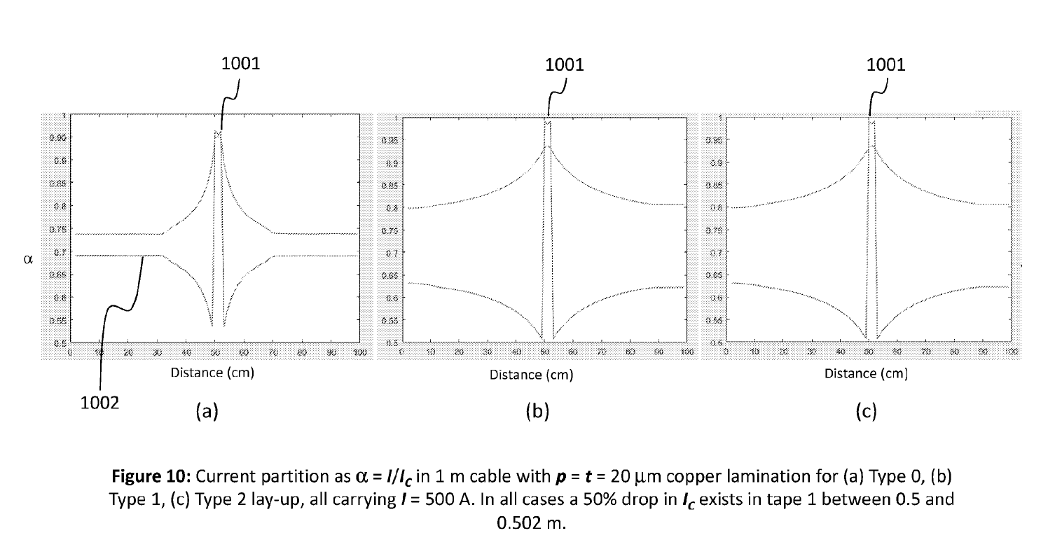

The impact of a 50% drop in critical current over a 2 mm length 1001 in tape 1 1002 of a pair of tapes, both 1 m long, has been modelled, first with t=p=20 μm, uniform I_{C}=350 A along their length, and I=500 A. The results are shown in FIG. 10(a-c) in terms of α=I/I_{C} for types 0, 1 & 2. In all cases current commutes between tapes to minimise power dissipation around the dropout 1001, with current leaving tape 1 before the flaw and returning after the flaw. The amount of current that leaves tape 1 is enough to keep the current in tape 1 just below I_{C} since this minimises total dissipation. However, the distance over which this occurs is longer for type 1 and type 2 layup than for type 0 and the total dissipation is 2.4 times more for type 1 and 2 than type 0. If the stabilizer thickness is increased to p=t=100 μm the current distributions are similar but the dissipation decreases by 20% for type 1 and 2.

These results suggest that type 0 pairs are better at tolerating dropouts than either type 1 or type 2, but the latter can be improved by extra copper stabilizer.

The results above lead to a preferred cable construction that will now be discussed. It has been established that a 100 kA cable for use in the pilot plant core outer layer will need more than 66 tapes. To make this cable tolerant of I_{C} dropouts the model results make it clear that it is highly desirable to arrange these as a stack of 33 type 0 pairs, so that there is a low resistance between the ReBCO side of each tape and the ReBCO side of one other tape to assist current sharing if one tape in the pair has an I_{C} dropout. However, this unavoidably results in type 2 lay-up between each type 0 pair. In practice it is desirable to share current between all the tapes of a cable as far as possible, for example when both tapes in a type 0 pair quench, and so current sharing between pairs is still desirable. This can be significantly improved if the thickness of copper between the tapes in each type 0 pair is increased. Fortuitously this extra copper has negligible effect on sharing of current between the two tapes making up each type 0 pair.

Therefore, a particularly beneficial arrangement for a high current cable is for the individual tapes to be arranged in type 0 pairs, where the ReBCO to ReBCO layers face each other, with 100-800 μm of copper in total between the tapes (ie: 20-400 μm stabilizer thickness per tape, on the ReBCO face). These pairs are stacked and connected at the edges. The width of copper overhang at the edges should be similar to the thickness of copper within each type 0 pair. Additional copper between the substrate sides of two pairs (i.e. in the type 2 configuration, between each type 0 pair) is not beneficial (but also not detrimental, other than taking up space).

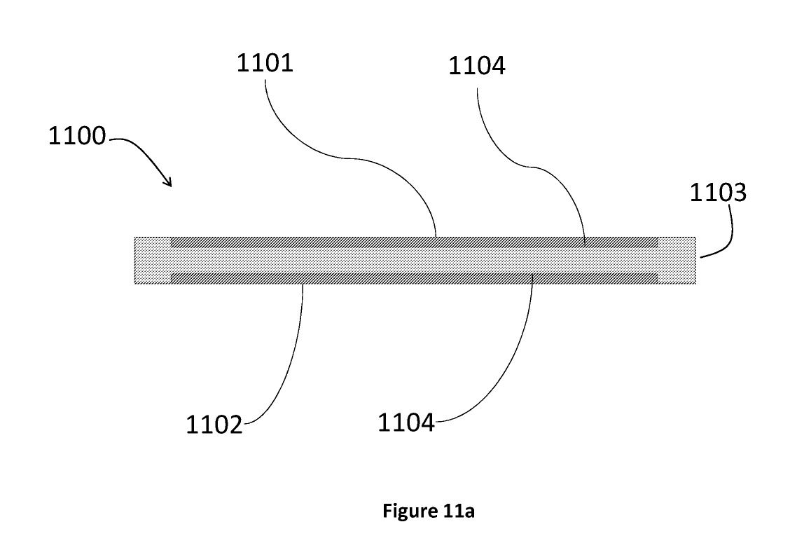

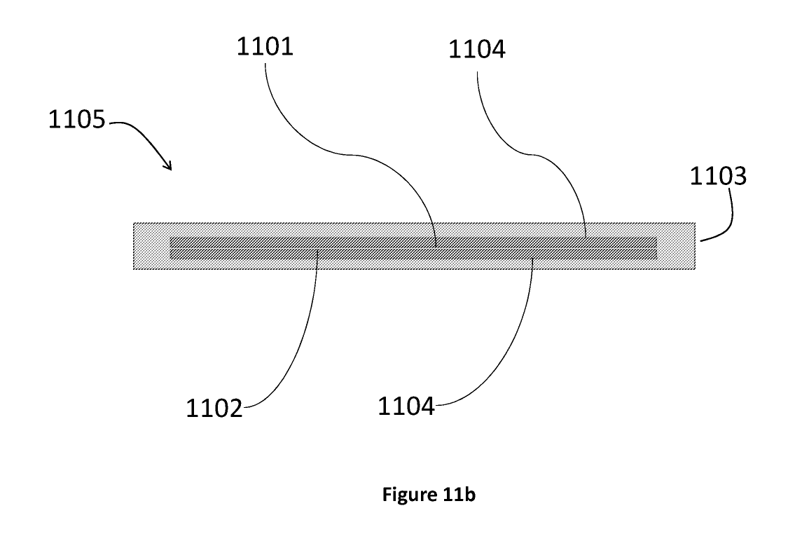

FIG. 11a is a cross-section through a single building block of such a cable, being a type 0 tape-pair 1100 made from two HTS tapes 1101, 1102, each having copper electroplating, arranged in type 0 configuration, with the ReBCO coated sides 1104 facing each other. Each tape is mounted into a recess in a thick copper lamination 1103. This construction of type 0 pair is the preferred building block for high current cables. The tapes may be soldered into this recess, or alternatively the loose tapes can be pressed together in situ. This would allow a degree of flexibility in the assembly. However in some circumstances pressed contacts may be too resistive. For 4 mm tape, the lamination 1103 may be between 50 to 800 μm in thickness (on top of the copper electroplating optionally included as part of the tape's manufacture). The thickness chosen will depend on the space available. In places where a lot of tapes are needed to carry 100 kA it may have to be 50 μm, but where only a few tapes are needed there is space for 800 μm.

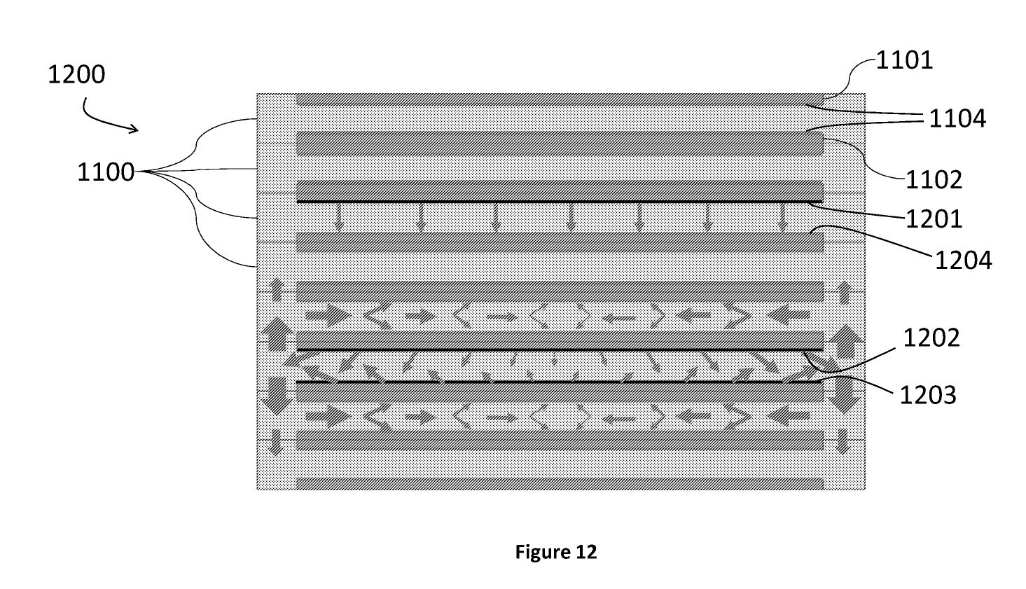

FIG. 12 is a schematic illustration of current sharing in a cable 1200 including eight such type 0 pairs 1100. The figure represents a cross section through the cable (so that current travels into the page along the ReBCO layers 1104). Suppose that one or more of the ReBCO layers 1201, 1202, 1203 have a downstream flaw reducing their current carrying capability (e.g. a crack or dropout or overheating). If only one tape 1201 in a pair is bad, current can switch to the other tape 1204 in that pair (as represented by the arrows). If both tapes 1202, 1203 in a pair are bad, current can flow into the copper between the ReBCO layers upstream then round the edge connections and into adjacent pairs in the stack. The thickness of the arrows roughly indicates the magnitude of current flow. More current leaves the ReBCO layers at the edges of the tape than in the middle, so it is beneficial to have several narrower tapes than one wide tape. Also, the thicker the copper layer, the easier it is for current to flow into it from the ReBCO layers.

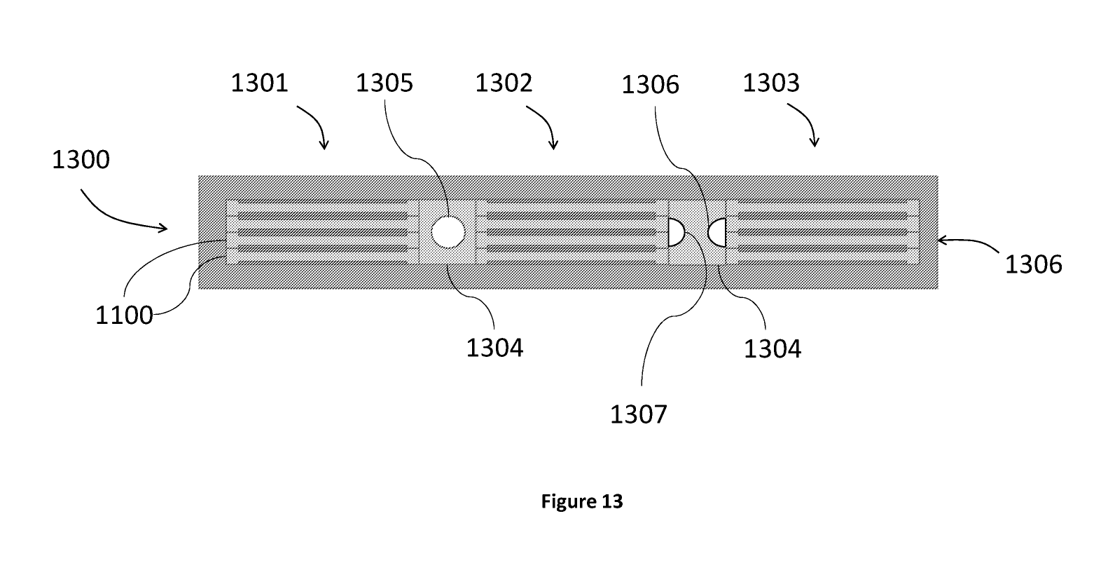

FIG. 13 shows an example of a cable arrangement 1300 with three stacks 1301, 1302, 1303 of four type 0 pairs of tapes arranged side-by-side. The stacks are spaced apart by spacers 1304. These spacers may optionally contain one or more cooling channels 1305, 1306, 1307. The spacers 1304 can be made from high strength material, such as stainless steel, to provide internal support, or from copper, to increase the electrical and thermal conductance between stacks and to the cooling channel. Alternatively the cooling channels may be located remotely outside the cable, between turns, and heat carried to them by conduction through the copper matrix. In this arrangement any hot spot forming between tapes due to a low I_{C} region is closely thermally coupled to a nearby cooling channel by a high conductivity path. The tape pair stacks are optionally encased in a structural jacket 1305 made from a high strength material such as stainless steel. It will be understood that it is possible to extend these examples to cables with tens of tape pairs, as needed for 100 kA capability.

The optional cooling channels 1306 carry a cryogenic coolant, such as helium, hydrogen, neon or similar cryogenic fluids in liquid, vapour, gas, 2-phase, or supercritical form. The channels 1306 are shown as a hole (extending into the page as a tube), but many other arrangements are possible, such a groove or slot 1307.

The width of the tapes used in each pair is a design choice, driven primarily by practical manufacturing, but it is somewhat desirable to use a larger number of narrower tapes (eg: 3 tapes of the standard 4 mm width) rather than fewer wide tapes (eg: a single 12 mm tape, being another standard width), because the narrower tapes have lower resistivity from their centre into the copper matrix compared to wider tapes with the same copper thickness between the pairs. Also, an I_{C} dropout in any one tape would affect a smaller proportion of the total current capability of the cable, and current sharing around the dropout is improved.

It may be preferable for various practical reasons, such as ease of manufacture and/or to allow increased flexibility of pre-formed cable sections, not to solder the tape stacks at the edges, but to rely instead on pressed electrical contacts. It is anticipated that this approach would benefit from additional thickness t and edge width p in the tape pairs.

The cable has been illustrated as a stack of type 0 pairs of HTS tape with the ReBCO layers facing the interior of the pair and a thick layer of copper in the middle of the pair. It will be appreciated that a similar effect can be achieved using type 2 pairs of tape as a building block 1105, as shown in FIG. 11b. Each type 2 pair would comprise a pair of HTS tapes 1101 stacked so that the substrates face each other, with a very thin (or even non-existent) layer of copper between them. There would then be a thick layer of copper between each type 2 pair 1105, and a thick layer of copper at the edge. The overall effect is the same, but there may be manufacturing advantages in preparing the building blocks as type 2 pairs with a thick external copper lamination, rather than type 0 pairs with a thick internal lamination.

The HTS tapes used in the stacked cable should have these desirable features:
Thinnest possible substrate to maximise space for copper. The substrate is only needed during tape manufacture and does not confer a structural benefit within the cable sections as described.
Lowest possible HTS-Ag—Cu interface resistivity, which seems to vary significantly between manufacturers.
Materials chosen to minimise activation during 14 MeV neutron bombardment, eg: remove Ni from substrate as this is activated into Co⁶⁰ which has a long half-life.
ReBCO layer has high resistance to damage by 14 MEV neutrons, maintaining good I_{C} over a long service life. This may be possible by simply increasing the thickness of the ReBCO layer. This is clearly advantageous for critical current carrying capability as well, and would decrease the number of tapes needed in a cable to carry the same current.

We now turn to methods for joints between cable sections. Two types of joint are possible: the “shaking hands” joint, in which the cable direction is essentially the same before and after the joint, and the “praying hands” joint, in which the cable reverses direction over the joint. The praying hands joint is more applicable where there is good deal of space around the joint, such as locations 507 and 508 in FIGS. 5A and 5B. It also has the potential benefit that the local magnetic field is largely cancelled thanks to the opposed current flow in each half of the joint.

Shaking hands joints would be needed to join the cables in the centre column at locations 505 and 506 in FIGS. 5A and 5B. A necessity for a joint in this position is that the joint takes up no more space than an unjointed cable. This rules out lap joints, where the individual tapes in the joint are overlapped. Butt joints would be feasible, but the limited contact area increases their resistance. The preferred joint is a tapered or scarfed joint, in which the tapes are tapered over a longitudinal distance several times the tape width.

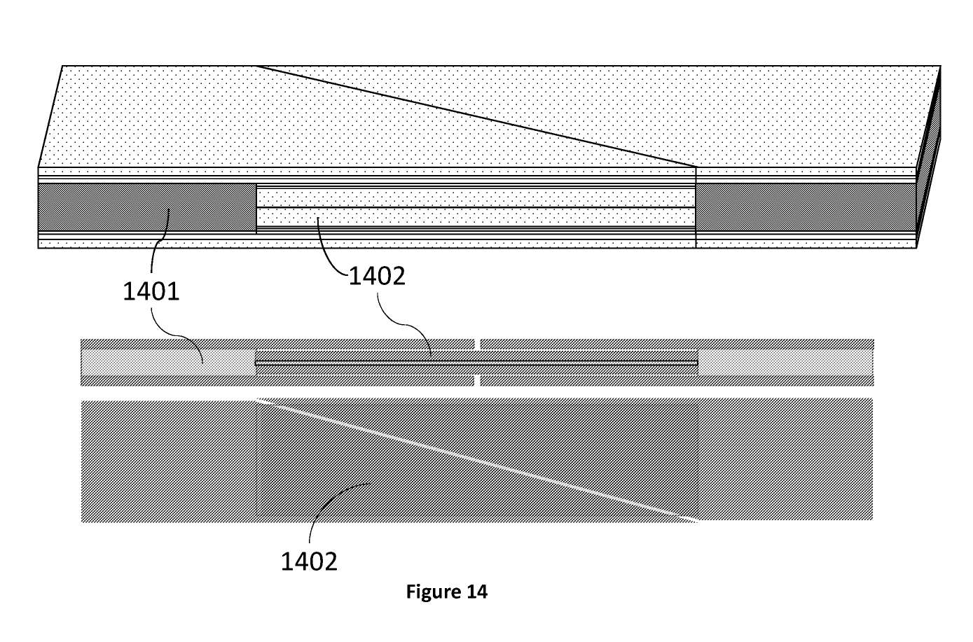

FIGS. 14 to 16 show three options for scarfed shaking hands joints between a type 0 pair. In FIG. 14 the additional Cu lamination 1401 between the tapes, as described above, is replaced with a pair of HTS tapes 1402 in type 2 configuration. This allows type 0 HTS face to HTS face connections between all tapes, which should result in the lowest resistance. The joint can be soldered, or simply pressed together, ideally with an indium film (not shown) applied between the mating faces. This type of joint is relatively complex and may be prone to hot spot formation due to the local reduction in copper fraction (tapes with 2-20 μm electroplated copper would be used).

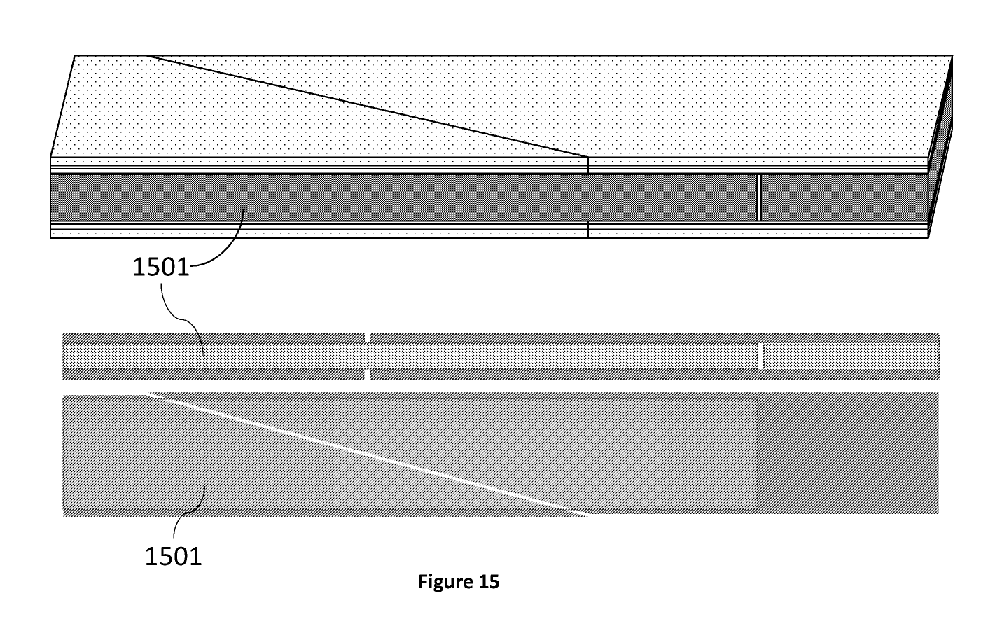

FIG. 15 shows a similar construction in which the type 2 pair of HTS tapes is replaced with a copper lamination 1501. Essentially the copper lamination between one of the type 0 pairs being joined is extended into the other. This arrangement allows current to flow from each HTS tape in one pair into the copper over a large surface area, and also leave the copper into the second pair over a large area. This is a simpler and more robust joint, but will have marginally higher resistance to that shown in FIG. 14. It would also be quite time consuming to make, requiring interleaving of each individual pair. It could be soldered or pressed as above.

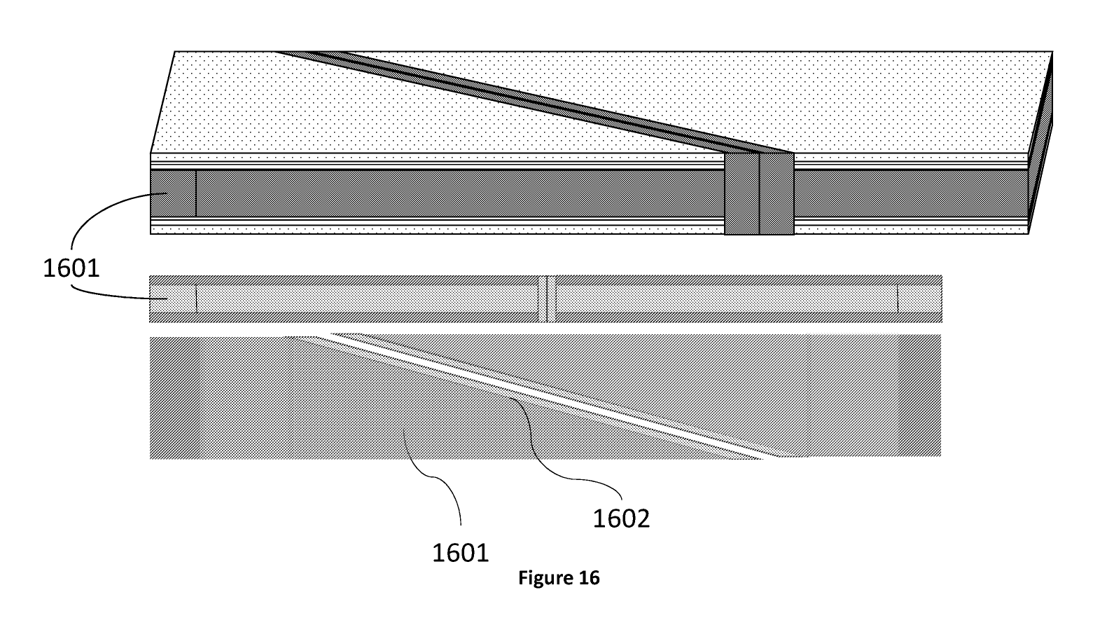

Finally FIG. 16 shows a third variant which is designed for ease of demountability, at the expense of higher resistance. A copper jointing piece 1601 is inserted between each pair which is scarfed to match the tapes but finished with a facing piece 1602 which maximises the surface area for the tapered butt connection between pairs. The faces of the connecting pieces in each pair can be pressed together or soldered, but this joint type is best suited to a pressed connection, optionally with indium foil inserted between the faces to reduce contact resistance. This is likely to be the most practical of the three joints for ease of assembly and disassembly, but also likely to have the highest resistance.

1. A cable for carrying electrical current in a coil of a magnet, comprising:
a stack of tape assemblies, each tape assembly comprising a high-strength metal substrate layer, and an HTS layer of high temperature superconductor, HTS, material;
wherein the tape assemblies are stacked as a series of type 0 pairs such that the HTS layers of a type 0 pair face each other and the substrate layers of the type 0 pair are separated by the HTS layers.

2. The cable of claim 1, wherein there is an internal layer of copper of thickness between about 20 μm and about 400 μm in each type 0 pair, the internal layer placed between the tape assemblies of the type 0 pair.

3. The cable of claim 1, wherein the internal layer of copper of each type 0 pair overhangs the edges of the tape for electrical connection to an adjacent type 0 pair in the stack.

4. The cable of claim 3, wherein a connection of the overhanging copper layers between type 0 pairs is a pressed, crimped or soldered connection.

5. The cable of claim 1, wherein stacks of type 0 tape pairs are arranged side-by-side with thermally and electrically conductive segments between the stacks.

6. The cable of claim 5, wherein some or all of the thermally conductive segments contain channels for the flow of cryogenic coolant.

7. The cable of claim 1, wherein the tape assemblies are incorporated in a copper matrix.

8. The cable of claim 1, wherein the tape assemblies are incorporated in a high strength structural jacket formed from material such as stainless steel or inconel.

9. The cable of claim 1, wherein there is at most 50 μm of copper between adjacent type 0 pairs of tape assemblies in the stack.

10. The cable of claim 1, wherein there is no copper between adjacent type 0 pairs of tape assemblies in the stack.

11. The cable of claim 1, wherein each HTS layer comprises ReBCO material.

12. A cable for carrying electrical current in a coil of a magnet, comprising:
a stack of tape assemblies and copper layers, each tape assembly comprising a substrate layer and an HTS layer of HTS material;
wherein the tape assemblies are stacked such that there is a layer of copper of thickness at least 100 μm, preferably at least 200 μm, more preferably at least 400 μm facing the HTS layer of each tape assembly.

13. A cable for carrying electrical current in a coil of a magnet, comprising:
a stack of tape assemblies, each tape assembly comprising a high-strength metal substrate layer, and an HTS layer of high temperature superconductor, HTS, material;
wherein the tape assemblies are stacked as a series of type 2 pairs such that the substrate layers of a type 2 pair face each other and the HTS layers of the type 2 pair are separated by the substrate layers.

14. The cable of claim 13, further comprising a layer of copper of thickness at least 40 μm, preferably at least 100 μm, more preferably at least 200 μm, more preferably at least 400 μm between each type 2 pair.

15. The cable of claim 1, configured to carry electrical current between joints with further cables.

16. The cable of claim 1, wherein the number of tape assemblies in the stack varies along the length of the cable.

17. The cable of claim 1, wherein each tape includes a silver layer adjacent to the HTS layer.

18. The cable of claim 1, wherein the width of the tape assemblies varies along the length of the cable.

19. The cable of claim 1, wherein the substrate does not contain nickel.

20. The cable of claim 1, wherein the stack is located within a pre-formed slot in a housing.

21. The cable of claim 20, wherein the housing is formed from thermally and electrically conductive material, optionally copper or stainless steel.

22. The cable of claim 20, further comprising a coolant channel in the slot adjacent the stack of tape assemblies.

23. A field coil comprising two or more cables according to claim 1 electrically connected at respective ends by a joint.

24. The field coil of claim 23, wherein the joint is a praying hands joint.

25. The field coil of claim 23, wherein the joint is a scarfed joint.

26. The field coil of claim 23, wherein a copper lamination between tape assemblies in a pair of tape assemblies is replaced in the joint by a pair of HTS tape assemblies.

27. The field coil of claim 23, wherein a copper lamination between tape assemblies in a pair of tape assemblies extends continuously into the joint.

28. The field coil of claim 23, wherein each pair of tape assemblies is terminated with a copper jointing piece to enable the cables to be pressed together.

29. A nuclear fusion reactor comprising a plasma vessel and a set of field coils for generating magnetic field, the field coils being field coils according to claim 23.
